(19) United States
(12) Patent Application Publication
(10) Pub. No.: US 2025/0098301 A1
(43) Pub. Date: Mar. 20, 2025

(54) GATE-TIE-DOWN IN BACKSIDE POWER ARCHITECTURE USING TRENCH-TIE-DOWN SCHEME

(71) Applicant: QUALCOMM Incorporated, San Diego, CA (US)

(72) Inventors: Deepak SHARMA, San Diego, CA (US); Yan SUN, San Diego, CA (US); Shreesh NARASIMHA, Charlotte, NC (US)

(21) Appl. No.: 18/469,483

(22) Filed: Sep. 18, 2023

(51) Int. Cl. H01L 27/12; H01L 21/768; H01L 23/528; H01L 29/775; H01L 29/786

(52) U.S. Cl. CPC H10D 86/60; H01L 21/76838; H01L 23/5286; H10D 30/43; H10D 30/6757; H10D 86/441

(57) ABSTRACT

Disclosed are gate-tie-down (GTD) cells that utilize a backside power delivery scheme, where metal wires that deliver power are provided on the back of the wafer. As a result, ultra-low height standard cell can be enabled. Also higher area scaling may be achieved. Further, performance and power gain can be maximized.

### FIELD OF DISCLOSURE

This disclosure relates generally to semiconductor devices, and more specifically, but not exclusively, to a novel structure to architecture gate-tie-down (GTD) in backside power architecture using a trench-tie-down (TDD) scheme, and fabrication techniques thereof.

### BACKGROUND

Integrated circuit (IC) technology has achieved great strides in advancing computing power through miniaturization of active components. In IC technology, a cell may be viewed as a circuitry that provides a logic function such as AND, NOT, OR, etc. Gate-tie-down (GTD) enables an electrical diffusion break and avoids the need for physical diffusion break. Conventional GTD schemes normally implement frontside power designs, where the metal wires are on the front face of the wafer. Unfortunately, this generally requires wider power rails and larger/taller logic cell.

Accordingly, there is a need for systems, apparatus, and methods that overcome the deficiencies of conventional devices including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary gate-tie-down (GTD) cell is disclosed. The cell may comprise first and second edge gates extending in a first direction. The first and second edge gates may define boundaries of the GTD cell. The cell may also comprise a channel ribbon extending in a second direction different from the first direction from the first edge gate to the second edge gate. The channel ribbon may be formed at least partially within the first and second edge gates. The cell may further comprise a backside power (BSP) rail extending in the second direction. The BSP rail may be formed below the first and second edge gates and below the channel ribbon. The cell may yet comprise a BSP trench extending in the second direction. The BSP trench may be formed on the BSP rail. The BSP trench may be conductive and electrically coupled with the BSP rail and with the first and second edge gates. A first edge portion of the channel ribbon within the first edge gate may be configured to prevent a first channel being formed therein when a turn-off voltage is applied to the first edge gate. A second edge portion of the channel ribbon within the second edge gate may be configured to prevent a second channel being formed therein when the turn-off voltage is applied to the second edge gate. The BSP rail may be configured to apply the turn-off voltage to the first and second edge gates through the BSP trench.

A method of fabricating a gate-tie-down (GTD) cell is disclosed. The method may comprise forming first and second edge gates extending in a first direction. The first and second edge gates may define boundaries of the GTD cell. The method may also comprise forming a channel ribbon extending in a second direction different from the first direction from the first edge gate to the second edge gate. The channel ribbon may be formed at least partially within the first and second edge gates. The method may further comprise forming a backside power (BSP) rail extending in the second direction. The BSP rail may be formed below the first and second edge gates and below the channel ribbon. The method may yet comprise forming a BSP trench extending in the second direction. The BSP trench may be formed on the BSP rail. The BSP trench may be conductive and electrically coupled with the BSP rail and with the first and second edge gates. A first edge portion of the channel ribbon within the first edge gate may be configured to prevent a first channel being formed therein when a turn-off voltage is applied to the first edge gate. A second edge portion of the channel ribbon within the second edge gate may be configured to prevent a second channel being formed therein when the turn-off voltage is applied to the second edge gate. The BSP rail may be configured to apply the turn-off voltage to the first and second edge gates through the BSP trench.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 illustrates a conventional gate-tie-down cell.

FIG. 2 illustrates a gate-tie-down cell in accordance with one or more aspects of the disclosure.

FIG. 3A-3D illustrate cross sections of the gate-tie-down cell of FIG. 2 in accordance with one or more aspects of the disclosure.

FIGS. 4A-11B illustrate examples of stages of fabricating a gate-tie-down cell in accordance with one or more aspects of the disclosure.

FIGS. 12-14 illustrate flow charts of example methods of fabricating a gate-tie-down cell in accordance with one or more aspects of the disclosure.

FIG. 15 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising.” “includes,” and/or “including.” when used herein, specify the presence of stated features, integers, steps, operations, elements, and/or components, but do not preclude the presence or addition of one or more other features, integers, steps, operations, elements, components, and/or groups thereof.

As indicated above, a cell may be viewed as a circuitry that provides a logic function such as AND, NOT, OR, etc. Gate-tie-down (GTD) enables an electrical diffusion break and avoids the need for physical diffusion break. Conventional GTD schemes normally implement frontside power designs, where the metal wires are on the front face of the wafer.

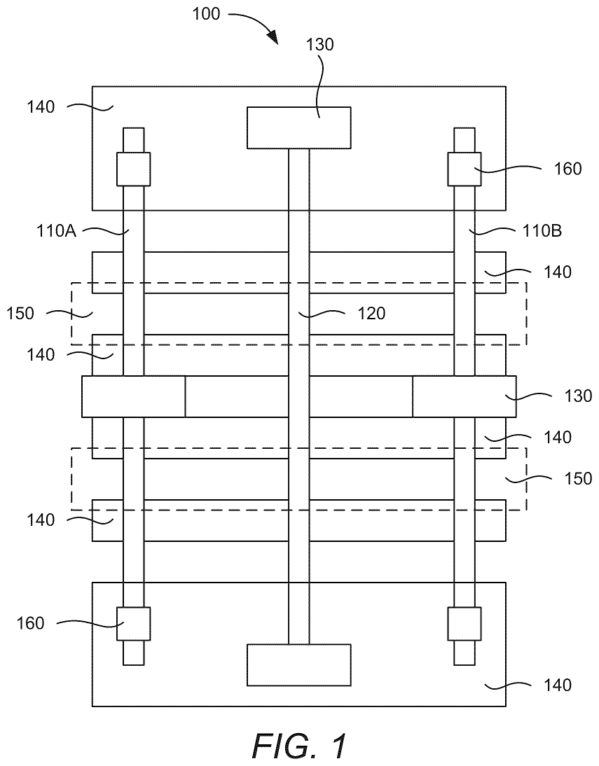

FIG. 1 illustrates a standard cell utilizing conventional GTD scheme. As seen, the cell 100 includes first and second edge gates 110A, 110B that extend in a vertical direction and an interior gate 120 that also extend in the vertical direction. The interior gate 120 is in between the first and second edge gates 110A, 110B. The conventional cell 100 also includes power rails 140 and channel ribbons 150 (shown as dashed boxes) that extend in a horizontal direction. The channel ribbons 150 are in between the power rails 140. The power rails 140 are electrically coupled with the edge gates 110A, 110B through tie down vias 160. Gate cuts 130 illustrate areas where portions of the gates (e.g., portions of the first and second edge gates 110A. 110B and/or of the interior gate 120) may be cut or otherwise removed.

In FIG. 1, upper and lower boundaries of the cell 100 may be defined by the upper and lower sides of the first and second edge gates 110A, 110B. Also, left and right boundaries of the cell may be defined by the first and second edge gates 110A, 110B. That is, in an aspect, it may be said that the first and second edge gates 110A, 110B define boundaries, at least in part, of the cell 100. The cell 100 should be isolated from other cells such as neighboring cells. In the GTD scheme, isolation is achieved electrically by applying a gate turn-off voltage (or more succinctly “turn-off” voltage) to the first and second edge gates 110A, 110B. When the turn-off voltage is applied to the first and second edge gates 110A, 110B, then no conductive channels are formed in the channel ribbons below the first and second edge gates 110A, 110B. Thus, isolation can be achieved electrically even if the channel ribbons 150 themselves physically continue outside the boundary of the cell 100. In other words, the channel ribbons 150 need NOT be physically broken. Thus, in this configuration, it is assumed that the power rails deliver the turn-off voltage. Such “electrical diffusion break” is desirable in that parametric variation is reduced when compared to cells with “physical diffusion break”.

In the cell 100 which employees conventional GTD scheme, the metal wires are on the front face of the wafer. In FIG. 1, this means that the power rails 140 are “above” the first and second edge gates 110A, 110B. As the technology scales, the cells become shorter. Unfortunately, achieving GTD with typical “frontside power” becomes more difficult. Generally, wider power rails and larger or taller logic cells are required, which is undesirable.

To address these and other issues of conventional GTD cell, it is proposed to use backside power through a trench format, i.e., through a trench-tie-down (TDD) approach. Using this approach, scaling of cells (e.g., smaller cells) while still using GTD can be enabled. There can be significant technical advantages in using the proposed TDD approach to achieve GTD. They include (not necessarily exhaustive):
Enable ultra-low height standard cell;
Achieve higher area scaling; and
Maximize performance and power gain.

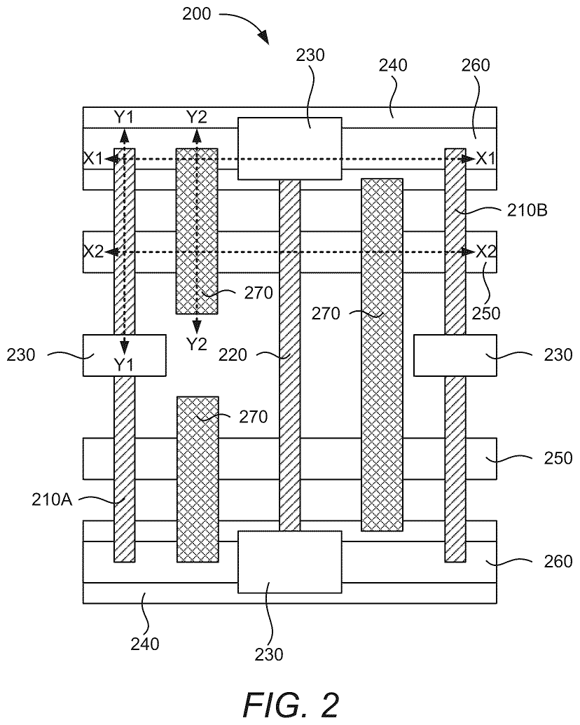

FIG. 2 illustrates an example of a gate-tie-down (GTD) cell in accordance with one or more aspects of the disclosure. In particular, a top view of cell 200 an example design implementation is shown in FIG. 2. The cell 200 may include first and second edge gates 210A, 210B (also generically referred to as edge gate or gates 210). The first and second edge gates 210A, 210B may extend in a first direction (e.g., vertical direction). An interior gate 120 extending in the first direction may be in between the first and second edge gates 210A, 210B. The edge gates 210A, 210B and/or the interior gate 220 may be formed from metals (e.g., copper (Cu), cobalt (Co), molybdenum (Mo), tungsten (W), ruthenium (Ru), titanium aluminide (TiAl), titanium nitride (TiN), etc.). While only one interior gate 220 is illustrated, there can be any number of interior gates 220 between the edge gates 210A, 210B. Gate cuts 230 illustrate areas where portions of the gates (e.g., portions of the first and second edge gates 210A, 210B and/or of the interior gate 220) may be cut or otherwise removed.

The cell 200 may also include one or more channel ribbons 250 extending in a second direction (e.g., horizontal direction) different from the first direction. In an aspect, the first and second directions may be orthogonal (or substantially orthogonal) to each other. The channel ribbons 250 may be formed from silicon (Si) or other semiconductor materials such as silicon germanium (SiGe), gallium arsenide (GaAs), and so on. The channel ribbons 250 may be formed, at least partially, within the first and second edge gates 210A, 210B and/or the interior gate 220. The cell 200 may be a fin-shaped field effect transistor (FinFET) cell. That is, the channel ribbons 250 may fins of a FinFET device. Alternatively, the cell 200 may be a gate all around (GAA) cell. That is, the channel ribbons 250 may be nanosheets of a GAA device.

The cell 200 may further include one or more backside power (BSP) rails 240 extending in the second (e.g., horizontal) direction. The BSP rails 240 may be placed below the channel ribbons 250. The BSP rails 240 may be formed from metals (e.g., Cu, Co, Mo, W. Ru, TiAl, TiN, etc.).

The cell 200 may yet include one or more BSP trenches 260 extending in the second (e.g., horizontal) direction. In an aspect, each BSP trench 260 may be formed on the corresponding BSP rail 240. The BSP trenches 260 may be conductive. For example, the BSP trenches 260 may be formed from metals such as Cu, Co, Mo, W, Ru, TiAl, TiN, etc, etc. The BSP trenches 260 may electrically couple the (e.g., the first and second edge gates 210A, 210B with the BSP rails 240. However, the interior gate 220 need NOT be electrically coupled to the BSP rails. The interior gate 220 may be configured to electrically coupled to one or more signal lines instead of the power lines.

The cell 200 may yet further include one or more trench contacts 270. The trench contacts 270 may electrically couple the BSP trenches 260 with sources/drains (S/D) of the cell 200.

In FIG. 2, first and second edge gates 210A, 210B may define the boundaries of the cell 200 in one direction (e.g., left and right boundaries) and the BSP trenches 260 may defined the boundaries in an orthogonal direction (e.g., top and bottom boundaries). In an aspect, the BSP rails 240 may be configured to apply a turn-off voltage (e.g., one of Vss and Vdd) to the first and second edge gates 210A, 210B through the BSP trenches 260. As a result, the cell 200 may be isolated from other cells, including neighboring cells that immediately abut the cell 200.

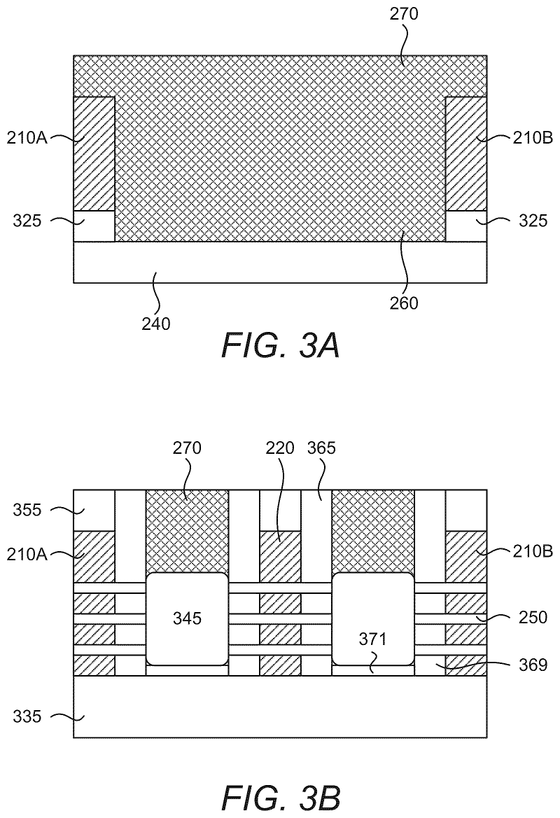

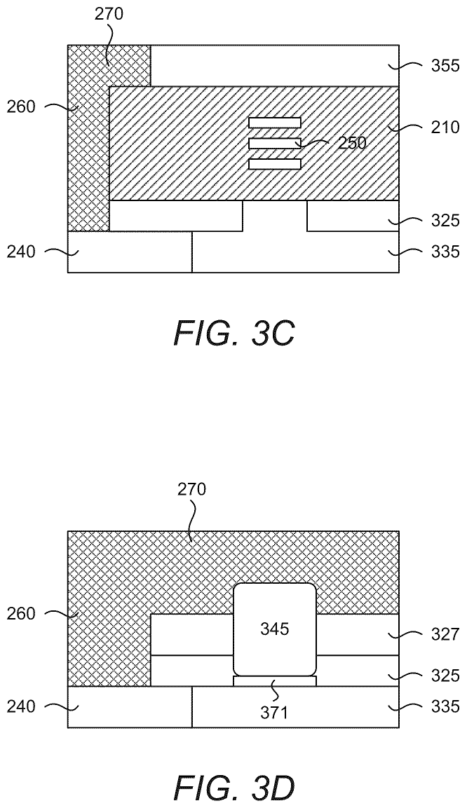

FIG. 3A illustrates a cross section of the cell 200 along X1-X1 cut line of FIG. 2. As seen, the cell 200 along this cross section may include the BSP rail 240, an oxide (or dielectric) 325 on the BSP rail 240, and first and second gates 210A, 210B on the oxide 325. In an aspect, the oxide 325 may serve as a shallow trench isolation (STI). The BSP trench 260 may be formed on the BSP rail 240. Recall that the BSP trench 260 may electrically couple the BSP rail 240 with the first and/or second edge gates 210A, 210B. In an aspect, the BSP trench 260 may be in direct contact with the BSP rail 240. Alternatively or in addition thereto, the BSP trench 260 may be in direct contact with the first and/or second gates 210A, 210B.

Trench contact 270 may be formed on the BSP trench 260. In an aspect, the trench contact 270 and the BSP trench 260 may be formed from same material (e.g., any one or more of Cu, Co. Mo. W. Ru, TiAl, TiN, etc.). Indeed, in another aspect, the trench contact 270 and the BSP trench 260 may be integrally formed.

FIG. 3B illustrates a cross section of the cell 200 along X2-X2 cut line of FIG. 2. As seen, the cell 200 along this cross section may include a backside dielectric 335. The first and second edge gates 210A, 210B as well as the interior gate 220 may be on the backside dielectric. Gate hard masks 355 may be on the first and second edge gates 210A, 210B and on the interior gate 220. One or more channel ribbons 250 may be formed above the backside dielectric 335. In an aspect, the channel ribbons 250 may be ribbons of a nanosheet wafer. At least one channel ribbon 250 may be formed such that the any one or more of the first and second edge gates 210A, 210B and/or the interior gate 220 at least partially surround the channel ribbon. That is, at least one channel ribbon 250 may be surrounded, at least partially by the first and second edge gates 210A, 210B and/or the interior gate 220.

For case of reference, a portion of the channel ribbon 250 within the first edge gate 210A may be referred to as a first edge portion. Also, a channel that may be formed in the first edge portion may be referred to as a first channel. Similarly, a portion of the channel ribbon 250 within the second edge gate 210B may be referred to as a second edge portion, and a channel that may be formed therein may be referred to as a second channel.

Recall from above that BSP rail 240 is configured to apply the turn-off voltage to the first and second edge gates 210A, 210B through the BSP trench 260. Accordingly, it then may be said that the first edge portion of the channel ribbon 250 is configured to prevent the first channel being formed therein when the turn-off voltage is applied to the first edge gate 210A. Similarly, it may be said that the second edge portion of the channel ribbon 250 is configured to prevent the second channel being formed therein when the turn-off voltage is applied to the second edge gate 210B.

Sources/drains (S/D) 345 may be formed in the channel ribbon 250 between each of the first and second edge gates 210A, 210B and the interior gate 220. The S/Ds 345 may be epitaxial. For case of reference, the S/D 345 between the first edge gate 210A and the interior gate 220 may be referred to as the first S/D 345, and the S/D 345 between the second edge gate 210B and the interior gate 220 may be referred to as the second S/D 345. Note that the channel ribbons 250 may be in electrical contact with the first and second S/Ds 345.

Trench contacts 270 may be formed on the S/Ds 345. For ease of reference, the trench contact 270 on the first S/D 345 may be referred to as a first trench contact 270, and the trench contact 270 on the second S/D 345 may be referred to as a second trench contact 270. The first trench contact 270 may be electrically coupled with the first S/D 345. For example, the first trench contact 270 may be in direct contact with the first S/D 345. Alternatively or in addition thereto, the second trench contact 270 may be electrically coupled with the second S/D 345. For example, the second trench contact 270 may be in direct contact with the second S/D 345. Spacers 365 may be formed between the gates (e.g., first and second edge gates 210A, 210B, interior gate 220) and the trench contacts 270. Also, inner spacers 369 may be formed between the gates (e.g., first and second edge gates 210A, 210B, interior gate 220) and the S/Ds 345. Epitaxial blocks 371 may be formed between the first and second S/Ds 345 and the backside dielectric 335.

In an aspect, one of the first and second trench contacts 270 may be electrically coupled with the BSP rail 240, e.g., through the BSP trench 260, while the other is NOT electrically coupled with the BSP rail 240. For example, the trench contact 270 that is electrically coupled may be in direct contact with the BSP trench 260.

As indicated above, the GTD nature of the cell 200 may electrically isolate the cell 200 when the first and second edge gates 210A, 210B are tied down by application of the turn-off voltage. This is even if the channel ribbon 250 physically extends beyond the cell boundaries. For example, the channel ribbon 250 may extend to the left beyond the first edge gate 210A (not shown) and/or may extend to the right beyond the second edge gate 210B (not shown). If the channel ribbon 250 extends left beyond the first edge gate 210A, then it may be said that the first edge portion electrically isolates a first inside portion from a first outside portion, where the first inside portion is defined as a portion of the channel ribbon 250 on a side of the first edge portion within the cell 200 and the first outside portion is defined as a portion of the channel ribbon 250 on a side of the first edge portion outside the cell 200. If the channel ribbon 250 extends right beyond the second edge gate 210B, then it may be said that the second edge portion electrically isolates a second inside portion from a second outside portion, where the second inside portion is defined as a portion of the channel ribbon 250 on a side of the second edge portion within the cell 200 and the second outside portion is defined as a portion of the channel ribbon 250 on a side of the second edge portion outside the cell 200.

While the first and second edge gates 210A, 210B only receive the turn-off voltage (e.g., one of Vss and Vdd), the interior gate 220 may receive the turn-off or a turn-on voltage (e.g., other of Vss and Vdd). For ease of reference, a portion of the channel ribbon 250 within the interior gate 220 may be referred to as an interior portion. Also, a channel that may be formed in the interior portion may be referred to as an interior channel. When the turn-on voltage is applied to the interior gate 220, then the interior channel may be formed, which may electrically couple the first and second S/Ds 345. Conversely, when the turn-off voltage is applied the interior gate 220, then the interior channel may be prevented from being formed.

FIG. 3C illustrates a cross section of the cell 200 along Y1-Y1 cut line of FIG. 2. As seen, the BSP rail 240 and the backside dielectric 335 may be provided. The BSP trench 260 and the trench contact 270 may be on the BSP rail 240, and the oxide 325 (e.g., serving as STI) may be on the BSP rail 240 and on the backside dielectric 335. The channel ribbon(s) 250 may formed within the gate 210 (e.g., first and/or second gates 210A, 210B).

Edge gate 210 (e.g., first edge gate 210A, second edge gate 210B) may be formed on the oxide 325 and on the backside dielectric 335. The channel ribbons 250 may vertically align, at least partially, with a portion of the backside dielectric 335 in contact with the gate 210. When translated to the first edge gate 210A, the channel ribbons 250 shown in FIG. 3C may correspond to the first edge portion. Alternatively or in addition thereto, when translated to the second edge gate 210B, the channel ribbons 250 shown in FIG. 3C may correspond to the first edge portion.

Note that the BSP trench 260 may be in direct contact with both the BSP rail 240 and the edge gate 210. FIG. 3C-like FIG. 3A-clearly illustrates that the gate-tie-down (GTD) is achieved through trench-tie-down (TDD) with the backside power (e.g., BSP rails 240). This is unlike the conventional GTD cell 100 illustrating a frontside power GTD scheme.

FIG. 3D illustrates a cross section of the cell 200 along Y2-Y2 cut line of FIG. 2. As seen, the BSP rail 240 and the backside dielectric 335 may be provided. The BSP trench 260 and the trench contact 270 may be on the BSP rail 240. The oxide 325 may be on the BSP rail 240 and on the backside dielectric 335. An interlayer dielectric (ILD) 327 may be on the oxide 325. Epitaxial block 371 and S/D 345 may also be formed—in that order—above backside dielectric 335.

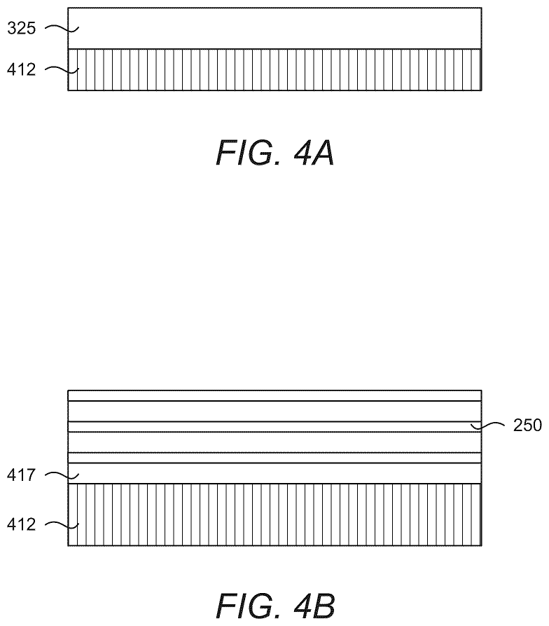

FIGS. 4A-11B illustrate examples of stages of fabricating a GTD cell, such as the GTD cell 200. FIGS. 4A, 5A, 6A, 7A, 8A, 9A, 10A and 11A illustrate stages related to the formation along the cutline X1-X1 cross section of FIG. 2, and FIGS. 4B, 5B, 6B, 7B, 8B. 9B. 10B and 11B illustrate stages related to the formation along the cutline X2-X2 cross section of FIG. 2. It is relatively straight to determine the processing steps to fabricate the cell 200 from these illustrations. For case of reference, the X1-X1 cross section may also be referred to as a “first area” of the GTD cell, and the X2-X2 cross section may also be referred to as a “second area” of the GTD cell. Note that the first and second areas may be parallel to each other.

FIGS. 4A and 4B illustrate a stage in which a substrate 412 (e.g., a carrier) may be provided. Along the X1-X1 cross section (FIG. 4A), oxide 325 may be provided on the substrate 412. Along the X2-X2 cross section (FIG. 4B), alternating dummy layers 417 (e.g., layers of SiGe) and channel ribbons 250 may be provided on the substrate 412. In an aspect, the substrate 412, the dummy layers 417, and the channel ribbons 250 may be a portion of a nanosheet wafer. In an aspect, the FIGS. 4A and 4B may illustrate a circumstance after the diffusion area (OD) is defined.

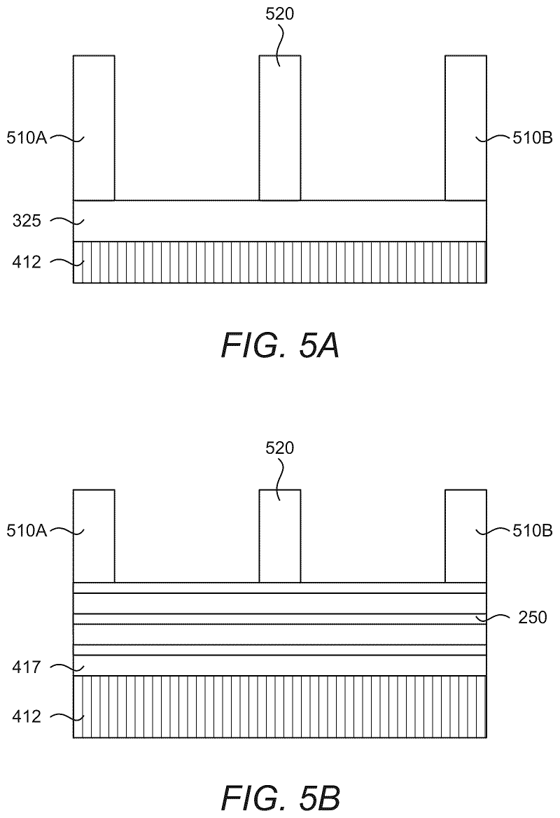

FIGS. 5A and 5B illustrate a stage in which dummy gates-first and second dummy edge gates 510A, 510B, and an interior dummy gate 520—may be formed on the oxide 325 (FIG. 5A) and on the channel ribbon 250 (e.g., of the nanosheet wafer) (FIG. 5B).

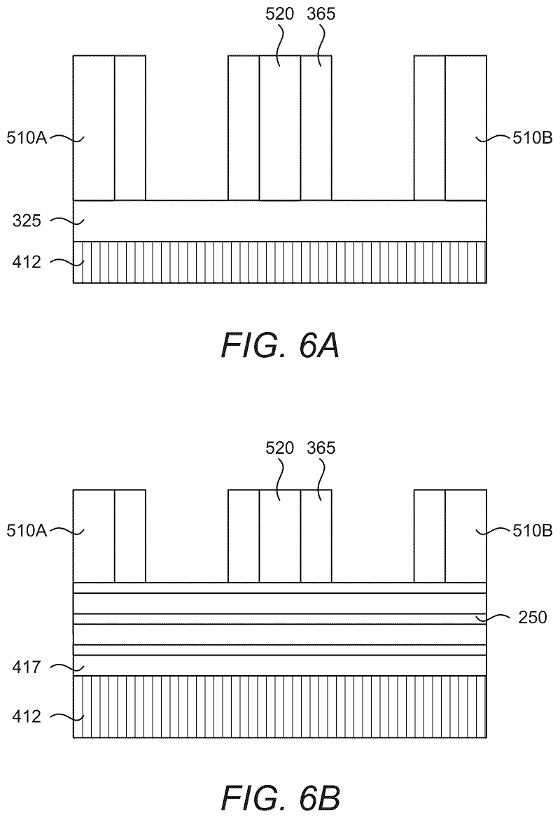

FIGS. 6A and 6B illustrate a stage in which the spacers 365 may be formed on the sides of the dummy gates (first and second dummy edge gates 510A, 510B, and interior dummy gate 520).

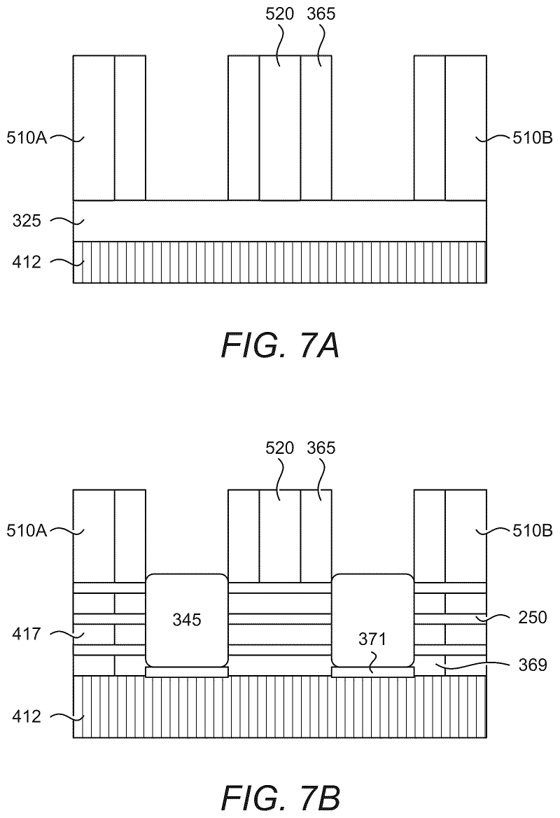

FIGS. 7A and 7B illustrate a stage in which S/Ds 345 may be formed along the X2-X2 cross section. For example, one S/D 345 may be formed between the first dummy edge gate 510A and the interior dummy gate 520 and another S/D 345 may be formed between the second dummy edge gate 510B and the interior dummy gate 520. For example, recesses may be formed in the nanosheet wafer between the first and second edge gates 210A, 210B and the interior gate 220. The recesses may expose the substrate 412. Epitaxial blocks 371 may be formed on the exposed portion of the substrate 412. Then the S/Ds 345 may be formed on the epitaxial blocks 371. Inner spacers 369 may also be formed on sides of the S/Ds 345 and the epitaxial blocks 371. The channel ribbons 250 may be in electrical contact with the S/Ds 345.

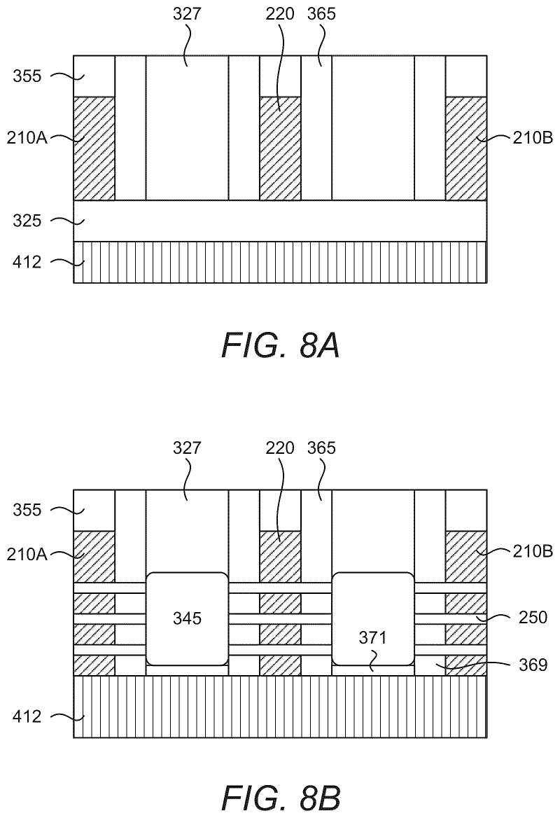

FIGS. 8A and 8B illustrate a stage in which the dummy gates (first and second dummy edge gates 510A, 510B, and interior dummy gate 520) may be released. In their place, the gates of the cell (first and second edge gates 210A, 210B, and interior gate 220) may be formed. Also, the gate hard masks 355 may be formed on the gates (first and second edge gates 210A. 210B, and interior gate 220) along the X2-X2 cross section. Further, ILD 327 may be deposited, e.g., to encapsulate the S/Ds 345. For example, after the ILD 327 is deposited, the first and second dummy gates 510A, 510B, and the interior dummy gate 520 may be released. This may be followed with metal deposition to form the gates 210A, 210B, 220, which may then be followed with gate hard mask 355 formation, e.g., through self-aligned contact (SAC) formation.

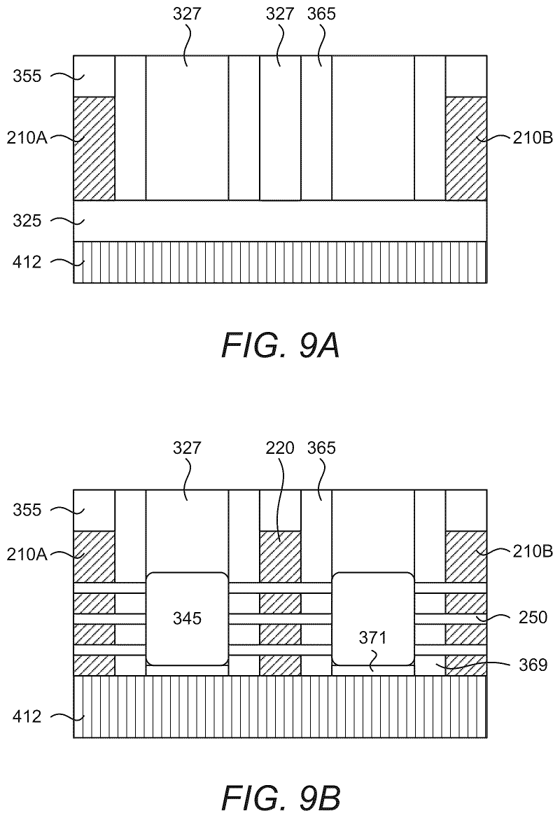

FIGS. 9A and 9B illustrate a stage in which gate cut is performed along the X1-X1 cross section to remove the interior gate 220. The space may be backfilled with more ILD 327.

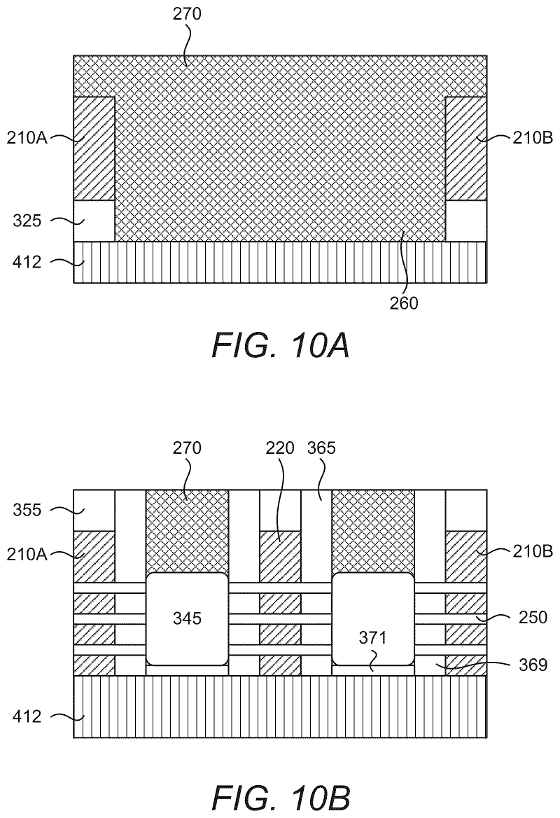

FIGS. 10A and 10B illustrate a stage in which the spacers 365 and the ILD 327 are removed along the X1-X1. The space left by the removal may then be filled with trench material (e.g., Cu, Co, Mo, W, Ru. TiAl, TiN, etc.) to form the BSP trench 260 and the trench contacts 270 may be formed. Upper surfaces of the gate hard masks 355, spacers 365, and the trench contacts 270 may be made coplanar, e.g., through polishing.

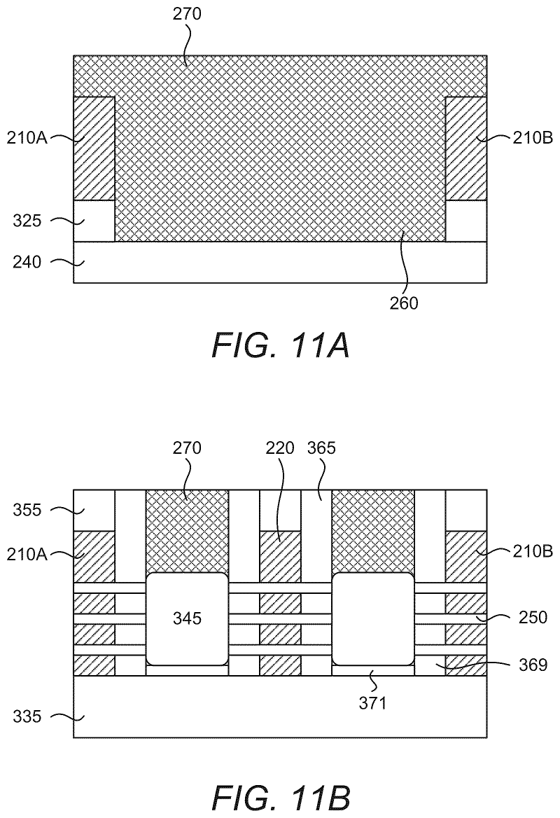

FIGS. 11A and 11B illustrate in which the substrate 412 may be removed. Thereafter, backside metallization process may be performed to provide the BSP rail 240. Backside dielectric 335 may also be provided.

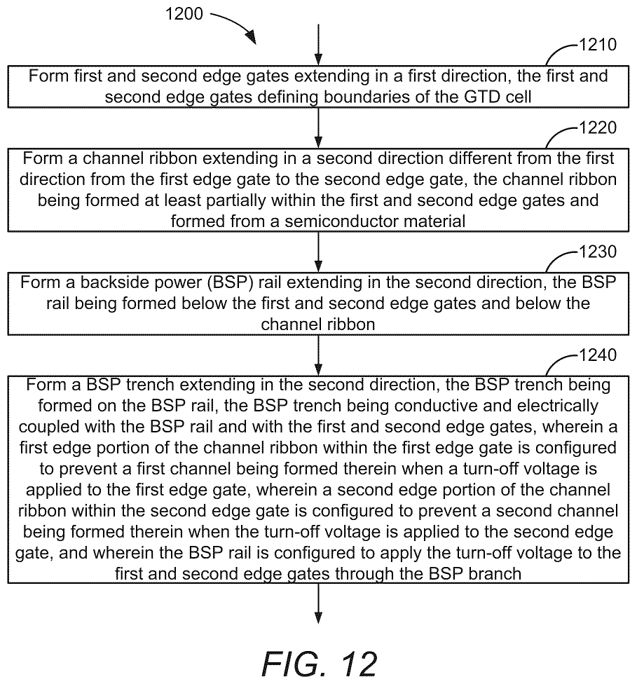

FIG. 12 illustrates a flow chart of an example method 1200 of fabricating a GTD cell, such as the cell 200 in accordance with one or more aspects of the disclosure. In block 1210, first and second edge gates 210A, 210B may be formed. The first and second edge gates 210A, 210B may extend in a first direction, and may define boundaries of the GTD cell 200, at least in part.

In block 1220, a channel ribbon 250 extending in a second direction from the first edge gate 210A to the second edge gate 210B may be formed. The second direction may be different from the first direction. The channel ribbon 250 may be formed at least partially within the first and second edge gates 210A. 210B. A first edge portion of the channel ribbon 250 within the first edge gate 210A may be configured to prevent a first channel being formed therein when a turn-off voltage is applied to the first edge gate 210A. A second edge portion of the channel ribbon 250 within the second edge gate 210B may be configured to prevent a second channel being formed therein when the turn-off voltage is applied to the second edge gate 210B.

In block 1230, a backside power (BSP) rail 240 extending in the second direction may be formed. The BSP rail 240 may be formed below the first and second edge gates 210A, 210B and below the channel ribbon 250.

In block 1240, a BSP trench 260 extending in the second direction may be formed. The BSP trench 260 may be formed on the BSP rail 240. The BSP trench 260 may be conductive and electrically coupled with the BSP rail 240 and with the first and second edge gates 210A, 210B. The BSP rail 240 may be configured to apply the turn-off voltage to the first and second edge gates 210A, 210B through the BSP trench 260.

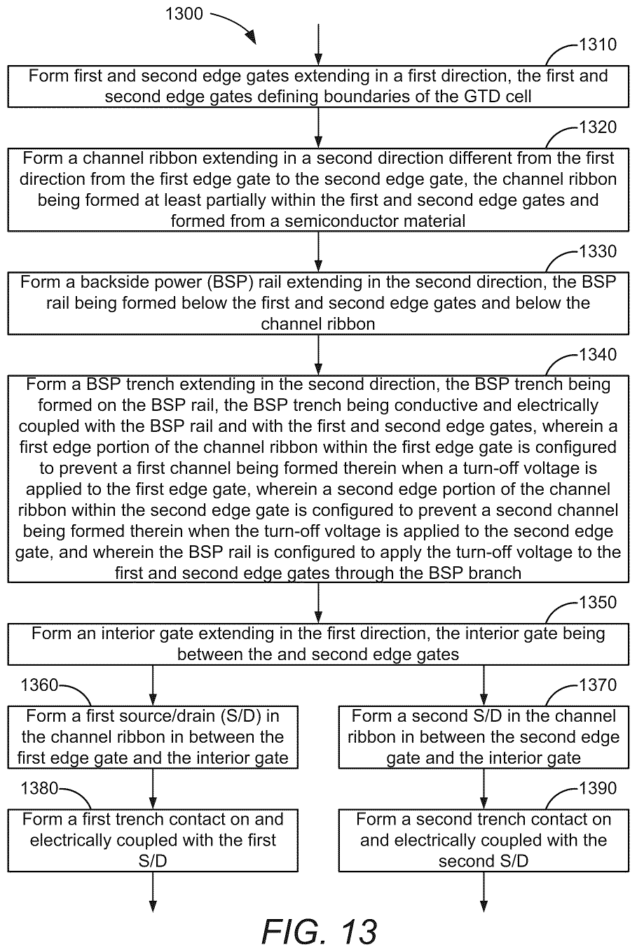

FIG. 13 a flow chart of an example method 1300 of fabricating a GTD cell, such as the cell 200 in accordance with one or more aspects of the disclosure. In an aspect, the method 1300 may be viewed as a more detailed version of the method 1200 to fabricate a GTD cell.

Block 1310 may be similar to block 1210. That is, in block 1310, first and second edge gates 210A. 210B may be formed. The first and second edge gates 210A, 210B may extend in a first direction, and may define boundaries of the GTD cell 200, at least in part.

Block 1320 may be similar to block 1220. That is, in block 1320, a channel ribbon 250 extending in a second direction from the first edge gate 210A to the second edge gate 210B may be formed. The second direction may be different from the first direction. The channel ribbon 250 may be formed at least partially within the first and second edge gates 210A, 210B. A first edge portion of the channel ribbon 250 within the first edge gate 210A may be configured to prevent a first channel being formed therein when a turn-off voltage is applied to the first edge gate 210A. A second edge portion of the channel ribbon 250 within the second edge gate 210B may be configured to prevent a second channel being formed therein when the turn-off voltage is applied to the second edge gate 210B.

Block 1330 may be similar to block 1230. That is, in block 1330, a backside power (BSP) rail 240 extending in the second direction may be formed. The BSP rail 240 may be formed below the first and second edge gates 210A, 210B and below the channel ribbon 250.

Block 1340 may be similar to block 1240. That is, in block 1340, a BSP trench 260 extending in the second direction may be formed. The BSP trench 260 may be formed on the BSP rail 240. The BSP trench 260 may be conductive and electrically coupled with the BSP rail 240 and with the first and second edge gates 210A, 210B. The BSP rail 240 may be configured to apply the turn-off voltage to the first and second edge gates 210A, 210B through the BSP trench 260.

In block 1350, an interior gate 220 extending in the first direction may be formed. The interior gate may be between the first and second edge gates 210A, 210B. The channel ribbon 250 may be at least partially within the interior gate 220. An interior portion of the channel ribbon 250 within the interior gate 220 may be configured to form an interior channel therein when a turn-on voltage is applied to the interior gate 220 and configured to prevent the interior channel from being formed therein when the turn-off voltage is applied to the interior gate 220.

In block 1360, a first source/drain (S/D) 345 may be formed in the channel ribbon 250 in between the first edge gate 210A and the interior gate 220. In block 1370, a second S/D 345 may be formed in the channel ribbon 250 in between the second edge gate 210B and the interior gate 220. When the turn-on voltage is applied to the interior gate 220, the interior channel may electrically couple the first and second S/Ds 345.

In block 1380, a first trench contact 270 may be formed on and electrically coupled with the first S/D 345. In block 1390, a second trench contact 270 may be formed on and electrically coupled with the second S/D 345.

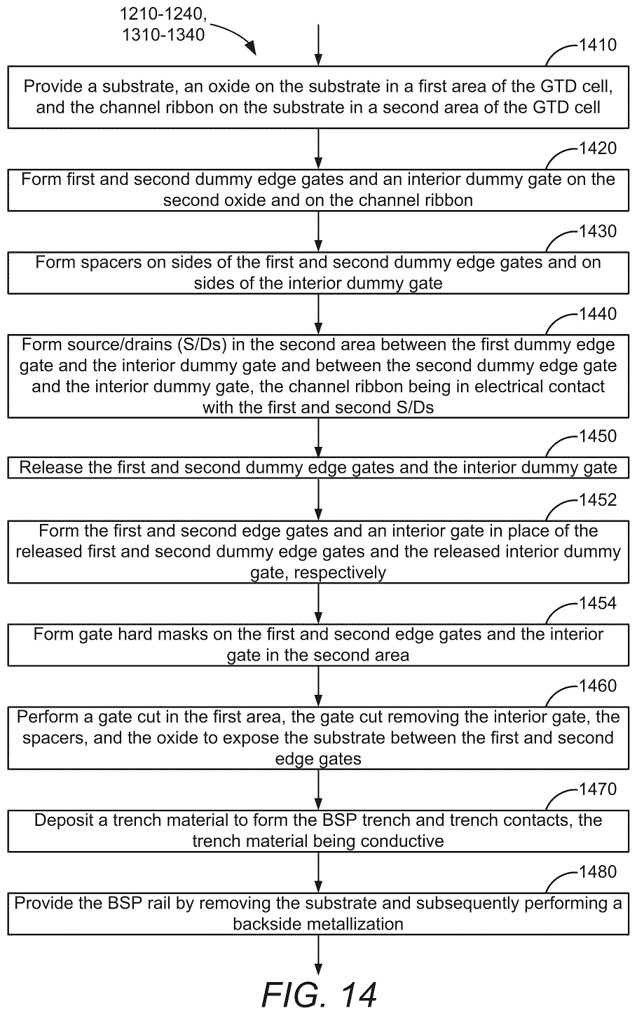

FIG. 14 illustrates an example implementation of blocks 1210-1240 and 1310-1340. In block 1410, a substrate 412 may be provided. The oxide 325 may be formed or otherwise provided on the substrate 412 in the first area (e.g., X1-X1 cross section) of the GTD cell 200. The channel ribbon 250 may be provided or formed on the substrate in the second area (e.g., X2-X2 cross section) of the GTD cell 200. For example, a nanosheet wafer may be provided in the second area. In an aspect, block 1410 may correspond to the stage illustrated in FIGS. 4A and 4B.

In block 1420, the first and second dummy edge gates 510A, 510B and the interior dummy gate 520 may be formed on the oxide 325 and on the channel ribbon 250. In an aspect, block 1420 may correspond to the stage illustrated in FIGS. 5A and 5B.

In block 1430, spacers 365 may be formed on sides of the first and second dummy edge gates 510A, 510B and on sides of the interior dummy gate 520. In an aspect, block 1430 may correspond to the stage illustrated in FIGS. 6A and 6B.

In block 1440, S/Ds 345 may be formed in the channel ribbon 250 in the second area between the first dummy edge gate 510A and the interior dummy gate 520 and between the second dummy edge gate 510B and the interior dummy gate 520. In an aspect, block 1440 may correspond to the stage illustrated in FIGS. 7A and 7B.

In block 1450, the first and second dummy edge gates 510A, 510B and the interior dummy gate 520 may be released.

In block 1452, the first and second edge gates 210A, 210B and the interior gate 220 may be formed in place of the released first and second dummy edge gates 510A, 510B and the released interior dummy gate 520, respectively.

In block 1454, the gate hard masks 355 may be formed on the first and second edge gates 210A, 210B and the interior gate 220 in the second area. In an aspect, blocks 1450, 1452 and 1454 may correspond to the stage illustrated in FIGS. 8A and 8B.

In block 1460, a gate cut may be performed in the first area. The gate cut may remove the interior gate 220, the spacers 365, and the oxide 325 to expose the substrate 412 between the first and second edge gates 210A, 210B. In an aspect, block 1460 may correspond to the stages illustrated in FIGS. 9A, 9B, 10A and 10B.

In block 1470, a trench material may be deposited to form the BSP trench 260 and trench contacts 270. The trench material (e.g., Cu, Co, Mo, W. Ru, TiAl, TiN, etc.) may be conductive. In an aspect, block 1470 may correspond to the stage illustrated in FIGS. 10A and 10B.

In block 1480, the BSP rail 240 may be provided by removing the substrate 412 and subsequently performing a backside metallization. In an aspect, block 1480 may correspond to the stage illustrated in FIGS. 11A and 11B.

The following should be noted regarding the flow indicated in FIGS. 12-14. Unless otherwise indicated, the flow of blocks do not necessarily limit the ordering in which the blocks may be performed. In otherwise, the blocks may be performed in any order that is logical.

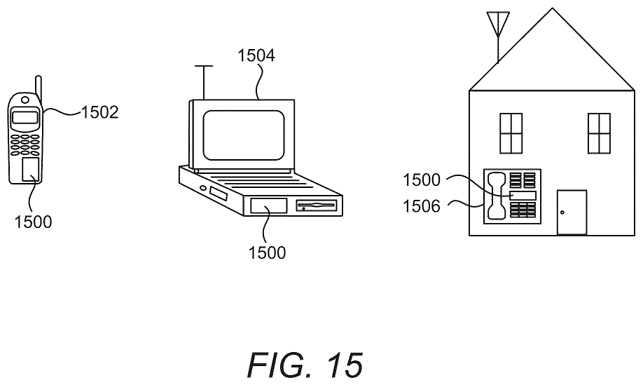

FIG. 15 illustrates various electronic devices 1500 that may be integrated with any of the aforementioned GAA devices in accordance with various aspects of the disclosure. For example, a mobile phone device 1502, a laptop computer device 1504, and a fixed location terminal device 1506 may each be considered generally user equipment (UE) and may include one or more cells (e.g., cells 200) as described herein. The devices 1502, 1504, 1506 illustrated in FIG. 15 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
Clause 1: A gate-tie-down (GTD) cell, comprising: first and second edge gates extending in a first direction, the first and second edge gates defining boundaries of the GTD cell; a channel ribbon extending in a second direction different from the first direction from the first edge gate to the second edge gate, the channel ribbon being formed at least partially within the first and second edge gates; a backside power (BSP) rail extending in the second direction, the BSP rail being formed below the first and second edge gates and below the channel ribbon; and a BSP trench extending in the second direction, the BSP trench being formed on the BSP rail, the BSP trench being conductive and electrically coupled with the BSP rail and with the first and second edge gates, wherein a first edge portion of the channel ribbon within the first edge gate is configured to prevent a first channel being formed therein when a turn-off voltage is applied to the first edge gate, wherein a second edge portion of the channel ribbon within the second edge gate is configured to prevent a second channel being formed therein when the turn-off voltage is applied to the second edge gate, and wherein the BSP rail is configured to apply the turn-off voltage to the first and second edge gates through the BSP trench.
Clause 2: The GTD cell of clause 1, wherein the first and second directions are orthogonal to each other.
Clause 3: The GTD cell of any of clauses 1-2, wherein the BSP trench is in direct contact with the BSP rail, the first edge gate, the second edge gate, or any combination thereof.
Clause 4: The GTD cell of any of clauses 1-3, wherein the first edge gate at least partially surrounds the first edge portion, or wherein the second edge gate at least partially surrounds the second edge portion, or both.
Clause 5: The GTD cell of any of clauses 1-4, wherein when the turn-off voltage is applied, the first edge portion electrically isolates a first inside portion from a first outside portion, or the second edge portion electrically isolates a second inside portion from a second outside portion, the first inside and outside portions being portions of the channel ribbon on sides of the first edge portion respectively within the GTD cell and outside the GTD cell, and the second inside and outside portions being portions of the channel ribbon on sides of the second edge portion respectively within the GTD cell and outside the GTD cell.
Clause 6: The GTD cell of any of clauses 1-5, further comprising: an interior gate extending in the first direction, the interior gate being between the first and second edge gates, wherein the channel ribbon is at least partially within the interior gate, and wherein an interior portion of the channel ribbon within the interior gate is configured to form an interior channel therein when a turn-on voltage is applied to the interior gate and configured to prevent the interior channel from being formed therein when the turn-off voltage is applied to the interior gate.
Clause 7: The GTD cell of clause 6, wherein the interior gate is not electrically coupled to the BSP rail.
Clause 8: The GTD cell of any of clauses 6-7, further comprising: a first source/drain (S/D) formed between the first edge gate and the interior gate above a backside dielectric, the channel ribbon being in electrical contact with the first S/D; and a second S/D formed between the second edge gate and the interior gate, the channel ribbon being in electrical contact with the second S/D, wherein when the turn-on voltage is applied to the interior gate, the interior channel electrically couples the first S/D with the second S/D.
Clause 9: The GTD cell of clause 8, further comprising: a first trench contact formed on and electrically coupled with the first S/D; and a second trench contact formed on and electrically coupled with the second S/D.
Clause 10: The GTD cell of clause 9, wherein one of the first and second trench contacts is electrically coupled with the BSP rail and other of the first and second trench contacts is not electrically coupled with the BSP rail.
Clause 11: The GTD cell of clause 10, wherein the one of the first and second trench contacts is in direct contact with the BSP trench.
Clause 12: The GTD cell of any of clauses 9-11, wherein the BSP trench, the first trench contact, and the second trench contact are formed from same material.
Clause 13: The GTD cell of any of clauses 1-12, wherein the BSP trench is formed from any one or more of copper (Cu), cobalt (Co), molybdenum (Mo), tungsten (W), ruthenium (Ru), titanium aluminide (TiAl), and titanium nitride (TiN).
Clause 14: The GTD cell of any of clauses 1-13, wherein the cell is a fin-shaped field effect transistor (FinFET) cell or a gate all around (GAA) cell.
Clause 15: The GTD cell of any of clauses 1-14, wherein the GTD cell is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 16: A method of fabricating a gate-tie-down (GTD) cell, the method comprising: forming first and second edge gates extending in a first direction, the first and second edge gates defining boundaries of the GTD cell; forming a channel ribbon extending in a second direction different from the first direction from the first edge gate to the second edge gate, the channel ribbon being formed at least partially within the first and second edge gates; forming a backside power (BSP) rail extending in the second direction, the BSP rail being formed below the first and second edge gates and below the channel ribbon; and forming a BSP trench extending in the second direction, the BSP trench being formed on the BSP rail, the BSP trench being conductive and electrically coupled with the BSP rail and with the first and second edge gates, wherein a first edge portion of the channel ribbon within the first edge gate is configured to prevent a first channel being formed therein when a turn-off voltage is applied to the first edge gate, wherein a second edge portion of the channel ribbon within the second edge gate is configured to prevent a second channel being formed therein when the turn-off voltage is applied to the second edge gate, and wherein the BSP rail is configured to apply the turn-off voltage to the first and second edge gates through the BSP trench.
Clause 17: The method of clause 16, wherein the first and second directions are orthogonal to each other.
Clause 18: The method of any of clauses 16-17, wherein the BSP trench is in direct contact with the BSP rail, the first edge gate, the second edge gate, or any combination thereof.
Clause 19: The method of any of clauses 16-18, wherein the first edge gate at least partially surrounds the first edge portion, or wherein the second edge gate at least partially surrounds the second edge portion, or both.
Clause 20: The method of any of clauses 16-19, wherein when the turn-off voltage is applied, the first edge portion electrically isolates a first inside portion from a first outside portion, or the second edge portion electrically isolates a second inside portion from a second outside portion, the first inside and outside portions being portions of the channel ribbon on sides of the first edge portion respectively within the GTD cell and outside the GTD cell, and the second inside and outside portions being portions of the channel ribbon on sides of the second edge portion respectively within the GTD cell and outside the GTD cell.
Clause 21: The method of any of clauses 16-20, further comprising: forming an interior gate extending in the first direction, the interior gate being between the first and second edge gates, wherein the channel ribbon is at least partially within the interior gate, and wherein an interior portion of the channel ribbon within the interior gate is configured to form an interior channel therein when a turn-on voltage is applied to the interior gate and configured to prevent the interior channel from being formed therein when the turn-off voltage is applied to the interior gate.
Clause 22: The method of clause 21, wherein the interior gate is not electrically coupled to the BSP rail.
Clause 23: The method of any of clauses 21-22, further comprising: forming a first source/drain (S/D) formed between the first edge gate and the interior gate above a backside dielectric, the channel ribbon being in electrical contact with the first S/D; and forming a second S/D formed between the second edge gate and the interior gate, the channel ribbon being in electrical contact with the second S/D, wherein when the turn-on voltage is applied to the interior gate, the interior channel electrically couples the first S/D with the second S/D.
Clause 24: The method of clause 23, further comprising: forming a first trench contact on and electrically coupled with the first S/D; and forming a second trench contact on and electrically coupled with the second S/D.
Clause 25: The method of clause 24, wherein one of the first and second trench contacts is electrically coupled with the BSP rail and other of the first and second trench contacts is not electrically coupled with the BSP rail.
Clause 26: The method of clause 25, wherein the one of the first and second trench contacts is in direct contact with the BSP trench.
Clause 27: The method of any of clauses 24-26, wherein the BSP trench, the first trench contact, and the second trench contact are formed from same material.
Clause 28: The method of any of clauses 16-27, wherein the BSP trench is formed from any one or more of copper (Cu), cobalt (Co), molybdenum (Mo), tungsten (W), ruthenium (Ru), titanium aluminide (TiAl), and titanium nitride (TiN).
Clause 29: The method of any of clauses 16-28, wherein the cell is a fin-shaped field effect transistor (FinFET) cell or a gate all around (GAA) cell.
Clause 30: The method of any of clauses 16-29, wherein forming the first and second edge gates, forming the channel ribbon, forming the backside power (BSP) rail, and forming the BSP trench comprises: providing a substrate, an oxide on the substrate in a first area of the GTD cell, and the channel ribbon on the substrate in a second area of the GTD cell; forming first and second dummy edge gates and an interior dummy gate on the oxide and on the channel ribbon; forming spacers on sides of the first and second dummy edge gates and on sides of the interior dummy gate; forming source/drains (S/Ds) in the second area between the first dummy edge gate and the interior dummy gate and between the second dummy edge gate and the interior dummy gate, the channel ribbon being in electrical contact with the first and second S/Ds; releasing the first and second dummy edge gates and the interior dummy gate; forming the first and second edge gates and an interior gate in place of the released first and second dummy edge gates and the released interior dummy gate, respectively; forming gate hard masks on the first and second edge gates and the interior gate in the second area; performing a gate cut in the first area, the gate cut removing the interior gate, the spacers, and the oxide to expose the substrate between the first and second edge gates; depositing a trench material to form the BSP trench and trench contacts, the trench material being conductive; and providing the BSP rail by removing the substrate and subsequently performing a backside metallization.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (Wi-Fi®), and IEEE 802.15.4 (Zigbee/Thread) or other protocols that may be used in a wireless communications network or a data communications network. Bluetooth® Low Energy (also known as Bluetooth® LE, BLE, and Bluetooth® Smart) is a wireless personal area network technology designed and marketed by the Bluetooth® Special Interest Group intended to provide considerably reduced power consumption and cost while maintaining a similar communication range. BLE was merged into the main Bluetooth® standard in 2010 with the adoption of the Bluetooth® Core Specification Version 4.0 and updated in Bluetooth® 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A gate-tie-down (GTD) cell, comprising:
first and second edge gates extending in a first direction, the first and second edge gates defining boundaries of the GTD cell;
a channel ribbon extending in a second direction different from the first direction from the first edge gate to the second edge gate, the channel ribbon being formed at least partially within the first and second edge gates;
a backside power (BSP) rail extending in the second direction, the BSP rail being formed below the first and second edge gates and below the channel ribbon; and
a BSP trench extending in the second direction, the BSP trench being formed on the BSP rail, the BSP trench being conductive and electrically coupled with the BSP rail and with the first and second edge gates,
wherein a first edge portion of the channel ribbon within the first edge gate is configured to prevent a first channel being formed therein when a turn-off voltage is applied to the first edge gate,
wherein a second edge portion of the channel ribbon within the second edge gate is configured to prevent a second channel being formed therein when the turn-off voltage is applied to the second edge gate, and
wherein the BSP rail is configured to apply the turn-off voltage to the first and second edge gates through the BSP trench.

2. The GTD cell of claim 1, wherein the first and second directions are orthogonal to each other.

3. The GTD cell of claim 1, wherein the BSP trench is in direct contact with the BSP rail, the first edge gate, the second edge gate, or any combination thereof.

4. The GTD cell of claim 1,
wherein the first edge gate at least partially surrounds the first edge portion, or
wherein the second edge gate at least partially surrounds the second edge portion, or
both.

5. The GTD cell of claim 1, wherein when the turn-off voltage is applied, the first edge portion electrically isolates a first inside portion from a first outside portion, or the second edge portion electrically isolates a second inside portion from a second outside portion,
the first inside and outside portions being portions of the channel ribbon on sides of the first edge portion respectively within the GTD cell and outside the GTD cell, and
the second inside and outside portions being portions of the channel ribbon on sides of the second edge portion respectively within the GTD cell and outside the GTD cell.

6. The GTD cell of claim 1, further comprising:
an interior gate extending in the first direction, the interior gate being between the first and second edge gates,
wherein the channel ribbon is at least partially within the interior gate, and
wherein an interior portion of the channel ribbon within the interior gate is configured to form an interior channel therein when a turn-on voltage is applied to the interior gate and configured to prevent the interior channel from being formed therein when the turn-off voltage is applied to the interior gate.

7. The GTD cell of claim 6, wherein the interior gate is not electrically coupled to the BSP rail.

8. The GTD cell of claim 6, further comprising:
a first source/drain (S/D) formed between the first edge gate and the interior gate above a backside dielectric, the channel ribbon being in electrical contact with the first S/D; and
a second S/D formed between the second edge gate and the interior gate, the channel ribbon being in electrical contact with the second S/D,
wherein when the turn-on voltage is applied to the interior gate, the interior channel electrically couples the first S/D with the second S/D.

9. The GTD cell of claim 8, further comprising:
a first trench contact formed on and electrically coupled with the first S/D; and
a second trench contact formed on and electrically coupled with the second S/D.

10. The GTD cell of claim 9, wherein one of the first and second trench contacts is electrically coupled with the BSP rail and other of the first and second trench contacts is not electrically coupled with the BSP rail.

11. The GTD cell of claim 10, wherein the one of the first and second trench contacts is in direct contact with the BSP trench.

12. The GTD cell of claim 9, wherein the BSP trench, the first trench contact, and the second trench contact are formed from same material.

13. The GTD cell of claim 1, wherein the BSP trench is formed from any one or more of copper (Cu), cobalt (Co), molybdenum (Mo), tungsten (W), ruthenium (Ru), titanium aluminide (TiAl), and titanium nitride (TiN).

14. The GTD cell of claim 1, wherein the cell is a fin-shaped field effect transistor (FinFET) cell or a gate all around (GAA) cell.

15. The GTD cell of claim 1, wherein the GTD cell is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

16. A method of fabricating a gate-tie-down (GTD) cell, the method comprising:
forming first and second edge gates extending in a first direction, the first and second edge gates defining boundaries of the GTD cell;
forming a channel ribbon extending in a second direction different from the first direction from the first edge gate to the second edge gate, the channel ribbon being formed at least partially within the first and second edge gates;
forming a backside power (BSP) rail extending in the second direction, the BSP rail being formed below the first and second edge gates and below the channel ribbon; and
forming a BSP trench extending in the second direction, the BSP trench being formed on the BSP rail, the BSP trench being conductive and electrically coupled with the BSP rail and with the first and second edge gates,
wherein a first edge portion of the channel ribbon within the first edge gate is configured to prevent a first channel being formed therein when a turn-off voltage is applied to the first edge gate,
wherein a second edge portion of the channel ribbon within the second edge gate is configured to prevent a second channel being formed therein when the turn-off voltage is applied to the second edge gate, and
wherein the BSP rail is configured to apply the turn-off voltage to the first and second edge gates through the BSP trench.

17. The method of claim 16, wherein the first and second directions are orthogonal to each other.

18. The method of claim 16, wherein the BSP trench is in direct contact with the BSP rail, the first edge gate, the second edge gate, or any combination thereof.

19. The method of claim 16,
wherein the first edge gate at least partially surrounds the first edge portion, or
wherein the second edge gate at least partially surrounds the second edge portion, or
both.

20. The method of claim 16, wherein when the turn-off voltage is applied, the first edge portion electrically isolates a first inside portion from a first outside portion, or the second edge portion electrically isolates a second inside portion from a second outside portion,
the first inside and outside portions being portions of the channel ribbon on sides of the first edge portion respectively within the GTD cell and outside the GTD cell, and
the second inside and outside portions being portions of the channel ribbon on sides of the second edge portion respectively within the GTD cell and outside the GTD cell.

21. The method of claim 16, further comprising:
forming an interior gate extending in the first direction, the interior gate being between the first and second edge gates,
wherein the channel ribbon is at least partially within the interior gate, and
wherein an interior portion of the channel ribbon within the interior gate is configured to form an interior channel therein when a turn-on voltage is applied to the interior gate and configured to prevent the interior channel from being formed therein when the turn-off voltage is applied to the interior gate.

22. The method of claim 21, wherein the interior gate is not electrically coupled to the BSP rail.

23. The method of claim 21, further comprising:
forming a first source/drain (S/D) formed between the first edge gate and the interior gate above a backside dielectric, the channel ribbon being in electrical contact with the first S/D; and
forming a second S/D formed between the second edge gate and the interior gate, the channel ribbon being in electrical contact with the second S/D,
wherein when the turn-on voltage is applied to the interior gate, the interior channel electrically couples the first S/D with the second S/D,
wherein when the turn-on voltage is applied to the interior gate, the interior channel electrically couples the first S/D with the second S/D.

24. The method of claim 23, further comprising:
forming a first trench contact on and electrically coupled with the first S/D; and
forming a second trench contact on and electrically coupled with the second S/D.

25. The method of claim 24, wherein one of the first and second trench contacts is electrically coupled with the BSP rail and other of the first and second trench contacts is not electrically coupled with the BSP rail.

26. The method of claim 25, wherein the one of the first and second trench contacts is in direct contact with the BSP trench.

27. The method of claim 24, wherein the BSP trench, the first trench contact, and the second trench contact are formed from same material.

28. The method of claim 16, wherein the BSP trench is formed from any one or more of copper (Cu), cobalt (Co), molybdenum (Mo), tungsten (W), ruthenium (Ru), titanium aluminide (TiAl), and titanium nitride (TiN).

29. The method of claim 16, wherein the cell is a fin-shaped field effect transistor (FinFET) cell or a gate all around (GAA) cell.

30. The method of claim 16, wherein forming the first and second edge gates, forming the channel ribbon, forming the backside power (BSP) rail, and forming the BSP trench comprises:
providing a substrate, an oxide on the substrate in a first area of the GTD cell, and the channel ribbon on the substrate in a second area of the GTD cell;
forming first and second dummy edge gates and an interior dummy gate on the oxide and on the channel ribbon;
forming spacers on sides of the first and second dummy edge gates and on sides of the interior dummy gate;
forming source/drains (S/Ds) in the second area between the first dummy edge gate and the interior dummy gate and between the second dummy edge gate and the interior dummy gate, the channel ribbon being in electrical contact with the first and second S/Ds;
releasing the first and second dummy edge gates and the interior dummy gate;
forming the first and second edge gates and an interior gate in place of the released first and second dummy edge gates and the released interior dummy gate, respectively;
forming gate hard masks on the first and second edge gates and the interior gate in the second area;
performing a gate cut in the first area, the gate cut removing the interior gate, the spacers, and the oxide to expose the substrate between the first and second edge gates;
depositing a trench material to form the BSP trench and trench contacts, the trench material being conductive; and
providing the BSP rail by removing the substrate and subsequently performing a backside metallization.
